(19) United States
(12) Patent Application Publication
(10) Pub. No.: US 2025/0115987 A1
(43) Pub. Date: Apr. 10, 2025

(54) MASK ASSEMBLY AND METHOD OF MANUFACTURING THE SAME

(71) Applicant: Samsung Display Co., Ltd., Yongin-si (KR)

(72) Inventors: Jeongkuk Kim, Yongin-si (KR); Kyongtae Yu, Yongin-si (KR); Sungwon Cho, Yongin-si (KR); Junho Jo, Yongin-si (KR)

(21) Appl. No.: 18/760,814

(22) Filed: Jul. 1, 2024

(30) Foreign Application Priority Data
Oct. 5, 2023 (KR) 10-2023-0132700

(51) Int. Cl. C23C 14/04; C23C 14/12; H10K 71/16

(52) U.S. Cl. CPC C23C 14/042; C23C 14/12; H10K 71/166

(57) ABSTRACT

A mask assembly includes: a mask frame having an opening region; and a first mask sheet covering the mask frame. The first mask sheet includes: a first layer including a plurality of first ribs extending in a first direction and a plurality of second ribs extending in a second direction crossing the first direction and having a plurality of first openings defined by the first ribs and the second ribs; a second layer on a first surface of the first layer and extending around the first openings; and a third layer on a second surface of the first layer and having a plurality of pattern holes overlapping the first openings.

### CROSS-REFERENCE TO RELATED APPLICATION

The present application claims priority to and the benefit of Korean Patent Application No. 10-2023-0132700, filed on Oct. 5, 2023, in the Korean Intellectual Property Office, the entire disclosure of which is incorporated herein by reference.

### BACKGROUND

### 1. Field

Aspects of embodiments of the present disclosure relate to a mask assembly and a method of manufacturing the same.

### 2. Description of the Related Art

Electronic devices have been widely used. Electronic devices have been variously used in mobile electronic devices and stationary electronic devices.

Electronic devices include display apparatuses that may provide users with visual information, such as images or videos, to support various functions.

A display apparatus that visually displays data may be formed by depositing various layers, such as an organic layer, an inorganic layer, a metal layer, etc. A deposition material may be deposited to form a plurality of layers of the display apparatus. For example, the deposition material may be ejected from (or emitted by) a deposition source and deposited on a display substrate through a mask assembly.

When the mask assembly is in close contact with the display apparatus, a shadow phenomenon may be reduced and deposition quality may be improved.

The above-described Background is information that the inventor(s) possessed for the derivation of the present disclosure or acquired in the process of deriving the present disclosure, and it may not form related (or prior) art.

### SUMMARY

Embodiments of the present disclosure include a mask assembly and a method of manufacturing the same, which can improve deposition quality.

However, such an aspect and feature is merely an example, and the aspects and features of the present disclosure are not limited thereto.

Additional aspects and features will be set forth, in part, in the description that follows and, in part, will be apparent from the description or may be learned by practice of the presented embodiments of the present disclosure.

According to an embodiment of the present disclosure, a mask assembly includes: a mask frame having an opening region; and a first mask sheet covering the mask frame. The first mask sheet includes: a first layer including a plurality of first ribs extending in a first direction and a plurality of second ribs extending in a second direction crossing the first direction and having a plurality of first openings defined by the first ribs and the second ribs; a second layer on a first surface of the first layer and extending around the first openings; and a third layer on a second surface of the first layer and having a plurality of pattern holes overlapping the first openings.

The first layer may further include a first through portion extending from a center of a width of the first ribs in a longitudinal direction of the first ribs and extending from a center of a width of the second ribs in a longitudinal direction of the second ribs.

When viewed from the second surface of the first layer, the second layer may cover the first through portion such that the second layer is exposed through the first through portion.

The first mask sheet may further include a first weld portion on the second layer exposed through the first through portion, and the first weld portion may be arranged along the first through portion in a plan view.

In a plan view, the first through portion, the second layer, and the first weld portion may overlap each other.

The mask assembly may further include a second mask sheet having second openings corresponding to the first openings, and the second mask sheet may be welded to the second layer by the first weld portion.

The first through portion may be formed in the form of a line in an extension direction of the first ribs and an extension direction of the second ribs.

The first through portion may be formed in the form of a plurality of dots that are spaced apart from each other in the longitudinal direction of the first ribs and the longitudinal direction of the second ribs.

The first layer may further include a second through portion extending along a circumference of the first layer.

When viewed from the second surface of the first layer, the second layer may cover the second through portion such that the second layer is exposed by the second through portion.

The first mask sheet may further include a second weld portion on the second layer exposed through the second through portion, and the second weld portion may be arranged along the second through portion in a plan view.

The second through portion may be formed in the form of a line extending along the circumference of the first layer.

The second through portion may be formed in the form of a plurality of dots that are spaced apart from each other along the circumference of the first layer.

According to another embodiment of the present disclosure, a method of manufacturing a mask assembly includes: arranging a first layer including a cell region; arranging, on a first surface of the first layer, a second layer including a metal material to extend around a periphery of the cell region; forming a first opening by etching the cell region of the first layer; forming a first through portion overlapping the second layer by etching the first layer to expose the second layer; and welded the exposed second layer to a mask sheet through the first through portion.

In a plan view, the first through portion may be formed in the form of a grid.

The method may further include arranging, on the first surface of the first layer, the second layer along a circumference of the first layer.

The method may further include forming a second through portion by etching the first layer to expose the second layer arranged along the circumference of the first layer.

The second through portion may be formed in the form of a line along the circumference of the first layer.

The second through portion may be formed in the form of a plurality of dots that are spaced apart from each other along the circumference of the first layer.

The method may further include welding the exposed second layer to the mask sheet through the second through portion.

Aspects and features other than those described above will become apparent from the following drawings, claims, and detailed description of embodiments of the present disclosure.

### BRIEF DESCRIPTION OF THE DRAWINGS

The above and other aspects and features of embodiments of the present disclosure will be more apparent from the following description taken in conjunction with the accompanying drawings, in which:

FIG. 1 is a cross-sectional view of an apparatus for manufacturing a display apparatus according to an embodiment;

FIG. 2 is a schematic cross-sectional view of a mask assembly according to an embodiment taken along the line II-II′ in FIG. 4;

FIG. 3 is a schematic plan view of a mask assembly according to an embodiment;

FIG. 4 is an enlarged view of the region IV in FIG. 3;

FIG. 5 is an enlarged view of the region IV in FIG. 3 according to another embodiment;

FIGS. 6 to 10 are schematic views of steps of a method of manufacturing a mask assembly according to an embodiment;

FIG. 11 is a schematic perspective view of a display apparatus manufactured by using an apparatus for manufacturing a display apparatus according to an embodiment;

FIG. 12 is an equivalent circuit diagram of one pixel circuit included in the display apparatus shown in FIG. 11; and

FIG. 13 is a schematic cross-sectional view of the display apparatus shown in FIG. 11.

### DETAILED DESCRIPTION

Reference will now be made, in detail, to embodiments, examples of which are illustrated in the accompanying drawings. In this regard, the described embodiments may have different forms and should not be construed as being limited to the descriptions set forth herein. Accordingly, embodiments are merely described below, by referring to the figures, to explain aspects and features of the present description. It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

In the following detailed description, the x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When a certain embodiment may be implemented differently, a specific process order may be performed differently from the described order. For example, two consecutively described processes may be performed concurrently or substantially at the same time or may be performed in an order opposite to the described order.

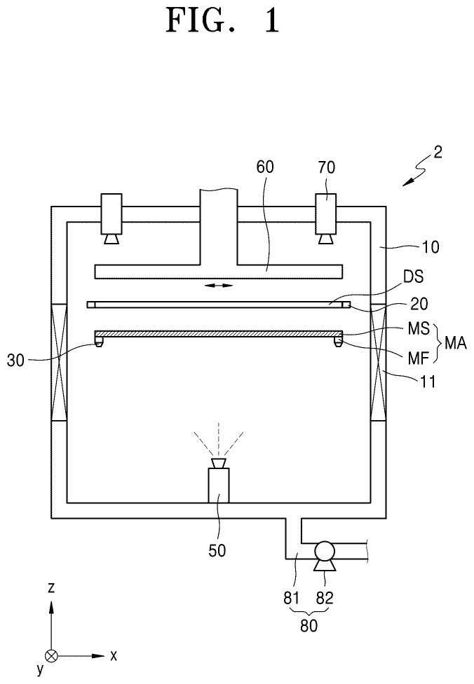

FIG. 1 is a cross-sectional view of an apparatus for manufacturing a display apparatus according to an embodiment.

An apparatus 2 for manufacturing a display apparatus may include a chamber 10, a first support portion 20, a second support portion 30, a mask assembly MA, a deposition source 50, a magnetic force portion 60, a vision portion 70, and a pressure control portion 80.

The chamber 10 may have a space formed therein, in which a display substrate DS and the mask assembly MA may be accommodated. A portion of the chamber 10 may be formed to be open, and a gate valve 11 may be provided in the open portion of the chamber 10. The open portion of the chamber 10 may be opened or closed depending on the operation of the gate valve 11.

The display substrate DS may refer to a display substrate DS during a process of manufacturing a display apparatus in which at least one of an organic layer, an inorganic layer, or a metal layer is deposited on a substrate 100, to be described in more detail below. In some embodiments, the display substrate DS may be a substrate 100 on which none of the organic layer, the inorganic layer, and the metal layer are deposited.

The first support portion 20 may support the display substrate DS. The first support portion 20 may be a plate fixed in the chamber 10. In another embodiment, the first support portion 20 is where the display substrate DS is placed and may be provided as a shuttle configured to perform linear motion inside the chamber 10. In another embodiment, the first support portion 20 may include an electrostatic chuck or an adhesive chuck that is fixed to the chamber 10 or arranged in the chamber 10 to be movable in the chamber 10 (e.g., moveably arranged in the chamber 10).

The second support portion 30 may support the mask assembly MA. The second support portion 30 may be arranged in the chamber 10. The second support portion 30 may be configured to perform fine adjustment(s) of the position of the mask assembly MA. The second support portion 30 may include a separate driving portion (e.g., a separate driver), an alignment unit, and the like to move the mask assembly MA in different directions.

In another embodiment, the second support portion 30 may be provided as a shuttle. In such an embodiment, the mask assembly MA is placed on the second support portion 30, and the second support portion 30 may transfer the mask assembly MA. For example, the second support portion 30 may move to the outside of the chamber 10 and may enter the chamber 10 from the outside after the mask assembly MA is placed thereon.

In the above embodiment, the first support portion 20 and the second support portion 30 may be integrally formed. In such an embodiment, the first support portion 20 and the second support portion 30 may each include a movable shuttle. The first support portion 20 and the second support portion 30 may include structures to fix the mask assembly MA and the display substrate DS thereon, with the display substrate DS being placed on the mask assembly MA and are configured to linearly move the display substrate DS and the mask assembly MA at the same time.

However, in the following description, for convenience of explanation, an embodiment in which the first support portion 20 and the second support portion 30 are separately formed at different positions in the chamber 10 is primarily described.

The deposition source 50 may be arranged to face the mask assembly MA. The deposition source 50 may include a deposition material, and by applying heat to the deposition material, the deposition material may evaporate or sublimate. The deposition source 50 may be arranged to be fixed in the chamber 10 or to be capable of performing linear motion in one direction in the chamber 10.

The mask assembly MA may be arranged in the chamber 10. The mask assembly MA may include a mask frame MF and a mask sheet MS, which is described below in more detail. The deposition material may be deposited on the display substrate DS through the mask assembly MA.

The magnetic force portion (e.g., the magnet or magnet plate) 60 may be arranged in the chamber 10 to face the display substrate DS and/or the mask assembly MA. The magnetic force portion 60 may apply a force to the mask assembly MA toward the display substrate DS by applying a magnetic force to the mask assembly MA. For example, the magnetic force portion 60 may not only prevent sagging of the mask sheet MS but may also move (or pull) the mask sheet MS to be adjacent to the display substrate DS. Furthermore, the magnetic force portion 60 may maintain a uniform distance between the mask sheet MS and the display substrate DS.

The vision portion 70 is arranged in the chamber 10 and may capture images of the positions of the display substrate DS and the mask assembly MA. The vision portion 70 may include a camera for capturing images of the display substrate DS and the mask assembly MA. The positions of the display substrate DS and the mask assembly MA may be identified based on the images captured by the vision portion 70, and thus, deformation of the mask assembly MA may be checked (e.g., measured). Furthermore, based on the images, the first support portion 20 may finely adjust the position of the display substrate DS or the second support portion 30 may finely adjust the position of the mask assembly MA. However, in the following description, an embodiment in which the second support portion 30 finely adjusts the position of the mask assembly MA to align the positions of the display substrate DS and the mask assembly MA is primarily described.

The pressure control portion 80 is connected to the chamber 10 and may control the pressure in the chamber 10. For example, the pressure control portion 80 may control the pressure in the chamber 10 to be the same as or similar to atmospheric pressure. Furthermore, the pressure control portion 80 may control the pressure in the chamber 10 to be the same as or similar to a vacuum state.

The pressure control portion 80 may include a connection pipe 81 connected to the chamber 10 and a pump 82 provided on (or along) the connection pipe 81. Depending on the operation of the pump 82, external air may be introduced into the chamber 10 through the connection pipe 81 or the gas inside the chamber 10 may be guided to (or evacuated to) the outside through the connection pipe 81.

In a method of manufacturing a display apparatus by using the apparatus 2 for manufacturing a display apparatus described above, first, the display substrate DS may be prepared.

The pressure control portion 80 may maintain the inside of the chamber 10 to be the same as or similar to atmospheric pressure, and the gate valve 11 is operated to open the the open portion of the chamber 10.

Then, the display substrate DS may be loaded from the outside of the chamber 10 into the inside thereof. The display substrate DS may be loaded into the chamber 10 by various methods. For example, the display substrate DS may be loaded from the outside of the chamber 10 into the inside of the chamber 10 by a robot arm and the like arranged outside the chamber 10. In another embodiment, when the first support portion 20 is a shuttle, the first support portion 20 may be carried out from the inside of the chamber 10 to the outside of the chamber 10, the display substrate DS placed on the first support portion 20 by another robot arm and the like arranged outside the chamber 10, and the first support portion 20 loaded from the outside of the chamber 10 into the chamber 10.

The mask assembly MA may be arranged in the chamber 10 as described above. In another embodiment, the mask assembly MA is loaded from the outside of the chamber 10 into the chamber 10 in a manner that is the same as or similar to the display substrate DS.

When the display substrate DS is loaded into the chamber 10, the display substrate DS may be placed on the first support portion 20. In this state, the vision portion 70 may capture images of the positions of the display substrate DS and the mask assembly MA. The positions of the display substrate DS and the mask assembly MA may be identified (or determined) based on the images captured by the vision portion 70. The apparatus 2 for manufacturing a display apparatus includes a separate controller to identify the positions of the display substrate DS and the mask assembly MA.

When the identification of the positions of the display substrate DS and the mask assembly MA is complete, the second support portion 30 may finely adjust the position of the mask assembly MA.

Then, as the deposition source 50 is operated, the deposition material may be supplied toward the mask assembly MA, and the deposition material passes through a plurality of pattern holes (or pattern openings) in the mask sheet MS to be deposited on the display substrate DS. In this state, the deposition source 50 may move parallel to the display substrate DS and the mask assembly MA, or the display substrate DS and the mask assembly MA may move parallel to the deposition source 50. For example, the deposition source 50 may move relative to the display substrate DS and the mask assembly MA. In this state, the pump 82 sucks (or evacuates) the gas from the chamber 10 and discharges the gas to the outside so that the pressure in the chamber 10 may be maintained to be the same as or similar to a vacuum state.

As described above, the deposition material supplied from the deposition source 50 passes through the mask assembly MA and is then deposited on the display substrate DS, and thus, at least one of a plurality of layers, for example, an organic layer, an inorganic layer, and a metal layer, to be stacked on a display apparatus, to be described below, may be formed.

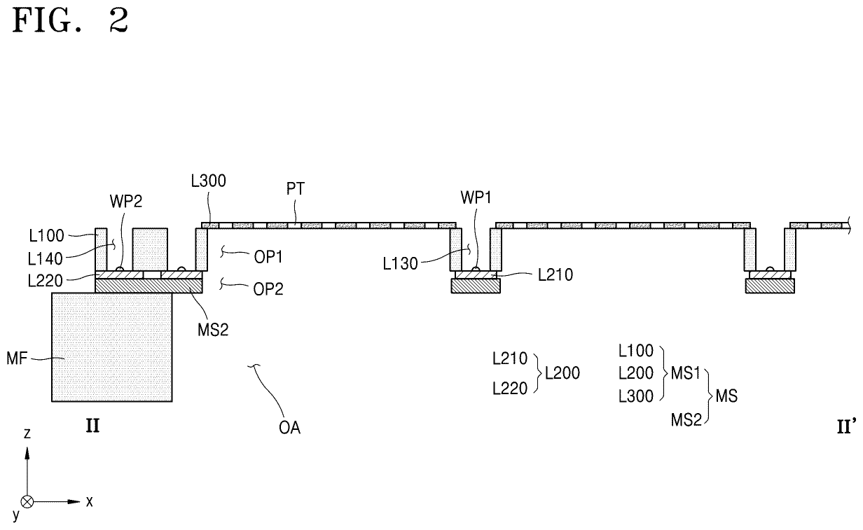

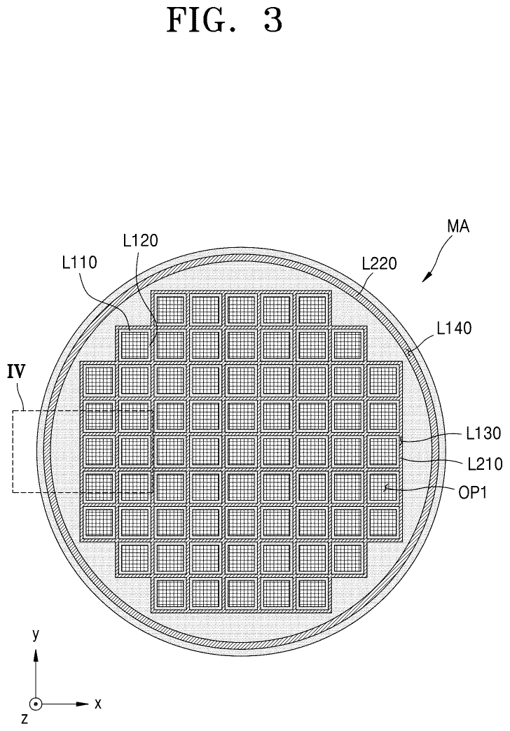

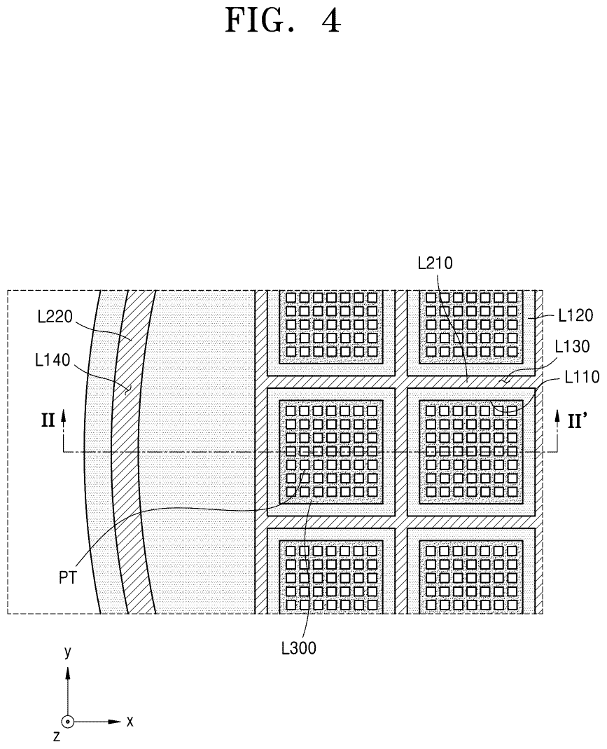

FIG. 2 is a schematic cross-sectional view of a mask assembly according to an embodiment taken along the line II-II′ in FIG. 4. FIG. 3 is a schematic plan view of a mask assembly according to an embodiment. FIG. 4 is an enlarged view of the region IV in FIG. 3.

Referring to FIGS. 2 to 4, the mask assembly MA may include the mask frame MF and the mask sheet MS.

The mask frame MF is a frame that supports the mask sheet MS and may be a frame that defines (or has) an opening region OA in the center thereof. In an embodiment, the mask frame MF is a circular frame, and the opening region OA may also be defined as a circle. However, the shape of the mask frame MF is not limited thereto and may have various polygonal shapes. In the following description, for convenience of explanation, an embodiment in which the mask frame MF is a circular frame is primarily described.

The mask sheet MS may be provided on the mask frame MF. The opening region OA in the center of the mask frame MF may be covered by the mask sheet MS. In an embodiment, the mask sheet MS may be fixed to the mask frame MF by welding. Furthermore, in an embodiment, the mask sheet MS may have a circular shape corresponding to the shape of the opening region OA in the mask frame MF.

The mask sheet MS may include a first mask sheet MS1 and a second mask sheet MS2. The first mask sheet MS1 may include a first layer L100, a second layer L200, and a third layer L300.

The first layer L100 may include a silicon material. For example, the first layer L100 may include at least one material selected from silicon oxide (SiOₓ), silicon nitride (SiNₓ), and silicon oxynitride (SiOₓN_{y}).

The first layer L100 may be formed to correspond to the shape of the mask frame MF. For example, the first layer L100 may be formed to have a circular shape to cover the opening region OA in the mask frame MF. However, the present disclosure is not limited thereto, and the first layer L100 may be formed to have various polygonal shapes. Hereinafter, for convenience of explanation, an embodiment in where the first layer L100 has a circular shape to correspond to the shape of the mask frame MF is primarily described.

The first layer L100 may have a plurality of first openings OP1. In an embodiment, each of the plurality of first openings OP1 may be formed to have a quadrangular shape. Each of the plurality of first openings OP1 may correspond to the shape of a display panel. In other words, each of the plurality of first openings OP1 may correspond to the shape of a cell.

In addition, the first layer L100 may include a first rib L110 extending in a first direction (e.g., an x direction of FIG. 3) and a second rib L120 extending in a second direction (e.g., a y direction of FIG. 3) crossing the first direction. In an embodiment, the first rib L110 and the second rib L120 may respectively include a plurality of first ribs L110 and a plurality of second ribs L120. The plurality of first ribs L110 may be spaced apart from each other in the second direction and may extend parallel to each other. The plurality of second ribs L120 may be spaced apart from each other in the first direction and may extend parallel to each other. The plurality of first ribs L110 and the plurality of second ribs L120 may be arranged in the form of a grid. In addition, the first openings OP1 may be defined by the plurality of first ribs L110 and the plurality of second ribs L120. For example, the first ribs L110 and the second ribs L120 may extend to surround (e.g., to extend around a periphery of) and define the first opening OP1.

The first layer L100 may have a first through portion L130 and a second through portion L140. The first through portion L130 may extend from the center of the width (e.g., the length in a y direction of FIG. 3) of the first rib L110 in the longitudinal direction (e.g., an x direction of FIG. 3) of the first rib L110 and may completely penetrate (or extend through) the first layer L100 in the thickness direction (e.g., a z direction of FIG. 3) of the first layer L100. For example, the first rib L110 may be separated into two parts with respect to the center of the width of the first rib L110 by the first through portion L130. In addition, the first through portion L130 may extend from the center of the width (e.g., the length in the x direction of FIG. 3) of the second rib L120 in the longitudinal direction (e.g., the y direction of FIG. 3) of the second rib L120 and may completely penetrate (or extend through) the first layer L100 in the thickness direction of the first layer L100. For example, the second rib L120 may be separated into two parts with respect to (or about) the center thereof in the width direction by the first through portion L130. Therefore, the first through portion L130 may penetrate (or extend through) the first layer L100 to form a grid as a whole in a plan view.

The second through portion L140 may extend along a circumference of the first layer L100 and may completely penetrate (or extend through) the first layer L100 in the thickness direction. In an embodiment, the second through portion L140 may be in the form of a line extending along the circumference of the first layer L100. The second through portion L140 may be located between the circumference of the first layer L100 and the first openings OP1. In addition, the second through portion L140 may be located between the circumference of the first layer L100 and the first through portion L130. In other words, in a plan view, the second through portion L140 may be arranged to surround (or may extend around a periphery of) the first openings OP1 and/or the first through portion L130.

In addition, in an embodiment, in a plan view, the second through portion L140 may have a shape corresponding to the shape of the circumference of the first layer L100. For example, when the shape of the circumference of the first layer L100 is circular, the second through portion L140 may also have a circular shape, such as a circular ring shape.

As described below, the first through portion L130 and the second through portion L140 may provide a passage through which welding may be performed.

The second layer L200 may be disposed on a first surface of the first layer L100. The first surface of the first layer L100 may refer to one surface of the first layer L100 facing the mask frame MF. In addition, a second surface of the first layer L100 facing the first surface of the first layer L100 may refer to one surface of the first layer L100 facing the display substrate DS.

The second layer L200 may include a metal material. For example, the second layer L200 may include at least one of aluminum (Al), copper (Cu), titanium (Ti), and molybdenum (Mo).

In a plan view, a first portion L210 of the second layer L200 may be arranged to surround (or to extend around a periphery of) the first openings OP1. In an embodiment, in a plan view, the first portion L210 may be arranged to overlap the first rib L110 and the second rib L120. For example, in a plan view, the first portion L210 may be arranged to overlap the first through portion L130. In other words, when viewed from the second surface of the first layer L100, the first portion L210 may be exposed by (or exposed through) the first through portion L130, and the first portion L210 may be disposed on the first surface of the first layer L100 to cover (or to extend over) the first through portion L130. Accordingly, the first portion L210 of the second layer L200 may be arranged in the form of a grid.

In a plan view, a second portion L220 of the second layer L200 may extend along the circumference of the first layer L100 and may be disposed on the first surface of the first layer L100. In an embodiment, in a plan view, the second portion L220 may be arranged to overlap the second through portion L140. For example, when viewed from the second surface of the first layer L100, the second portion L220 may be exposed by (or exposed through) the second through portion L140, and the second portion L220 may be disposed on the first surface of the first layer L100 to cover the second through portion L140. Accordingly, the second portion L220 of the second layer L200 may have a circular shape, such as a circular ring shape.

In addition, in an embodiment, the thickness of the second layer L200 may be at least about 3 μm but not more than about 10 μm. Accordingly, as described below, a sufficient thickness as a weldable base material may be provided.

The third layer L300 may be disposed on the second surface of the first layer L100. As described above, the second surface of the first layer L100 faces the first surface and may refer to one surface of the first layer L100 facing the display substrate DS.

In an embodiment, the third layer L300 may include a metal material. For example, the third layer L300 may include at least one of aluminum (Al), copper (Cu), titanium (Ti), and molybdenum (Mo). In another embodiment, the third layer L300 may include an inorganic material. For example, the third layer L300 may include at least one material selected from silicon oxide (SiOₓ), silicon nitride (SiNₓ), and silicon oxynitride (SiOₓN_{y}).

In a plan view, the third layer L300 may be arranged to cover (or to extend over) the first opening OP1 formed in the first layer L100. For example, the third layer L300 is provided as a plurality of parts, the number of which corresponds to the number of first openings OP1, and each of the parts may be arranged to cover each of the first openings OP1. In one embodiment, each part of the third layers L300 may have a plurality of pattern holes (e.g., pattern openings) PT overlapping the first opening OP1. In an embodiment, the shape of the plurality of pattern holes PT may correspond to the shape of a deposition pattern to be deposited on the display substrate DS. For example, the plurality of pattern holes PT may have a shape of an emission layer pattern of a pixel to be deposited on the display substrate DS. Accordingly, a deposition material may pass through the plurality of pattern holes PT to form an emission layer on the display substrate DS.

In addition, in an embodiment, the thickness of the third layer L300 may be at least about 1 μm but not more than about 2 μm.

The second mask sheet MS2 may include a metal material. For example, the second mask sheet MS2 may include at least one of aluminum (Al), copper (Cu), titanium (Ti), and molybdenum (Mo).

The second mask sheet MS2 may be arranged to face the second layer L200. For example, the second mask sheet MS2 may be arranged between the mask frame MF and the second layer L200. The second mask sheet MS2 may have second openings OP2 corresponding to the first openings OP1. For example, the second opening OP2 may have a shape and size corresponding to the shape and size of the first opening OP1, and the number of second openings OP2 may correspond to the number of first openings OP1. In an embodiment, the second mask sheet MS2 may be an open mask and may connect the second layer L200 to the mask frame MF.

In an embodiment, the thickness of the second mask sheet MS2 may be at least about 100 μm but not more than about 200 μm.

In addition, in a plan view, the second mask sheet MS2 may be arranged to overlap the second layer L200. For example, the second mask sheet MS2 may be arranged to overlap the second layer L200, such as the first portion L210. Accordingly, a portion of the second mask sheet MS2 may be arranged in the form of a grid.

In addition, the first mask sheet MS1 may include a first weld portion WP1 and a second weld portion WP2. The first weld portion WP1 may be disposed on the second layer L200 exposed through the first through portion L130, for example, on the first portion L210 of the second layer L200. The first weld portion WP1 may be a welding spot at where welding is performed, and the second layer L200 may be connected to the second mask sheet MS2 by welding through the first weld portion WP1. In an embodiment, the first weld portion WP1 may be arranged along the first through portion L130. For example, when the first through portion L130 is formed in the form of a grid as a whole in a plan view, the first weld portion WP1 may form a welding line in the form of a grid on the second layer L200 along the first through portion L130.

The second weld portion WP2 may be disposed on the second layer L200 exposed through the second through portion L140, such as on the second portion L220 of the second layer L200. The second weld portion WP2 may refer to a welding spot on which welding is performed, and the second layer L200 may be connected to the second mask sheet MS2 by welding through the second weld portion WP2. At this time, in an embodiment, the second weld portion WP2 may be arranged along the second through portion L140. For example, when the second through portion L140 is in the form of a line extending along the circumference of the first layer L100 in a plan view, the second weld portion WP2 may also form a welding line on the second layer L200 along the circumference of the first layer L100 along the second through portion L140. Accordingly, the second weld portion WP2 may have a circular ring shape.

According to embodiments, an integrated mask assembly MA may be provided. In other words, the first mask sheet MS1 and the second mask sheet MS2 may be welded and, thus, integrated through the first weld portion WP1 and the second weld portion WP2. In addition, because the second mask sheet MS2 is fixed to the mask frame MF, the first mask sheet MS1, the second mask sheet MS2, and the mask frame MF may be integrated.

In addition, a separate component, such as a mask supporter for bringing the mask assembly MA, including, a mask sheet, toward the display substrate DS, may be omitted. For example, because the second mask sheet MS2 is integrated with the first mask sheet MS1, the magnetic force of the magnetic force portion 60 of the apparatus for manufacturing a display apparatus may be applied to the second mask sheet MS2 that is relatively thick and includes a metal material. For example, the second mask sheet MS2 may act as an open mask and may accommodate (e.g., may simultaneously accommodate) the magnetic force of the magnetic force portion 60, and the mask assembly MA may be brought toward the display substrate DS and may be prevented from sagging.

Because the first layer L100 of the first mask sheet MS1 does not include a metal material and the third layer L300 is a very thin film having a thickness of at least about 1 μm but not more than about 2 μm, which is not thick enough to accommodate a magnetic force, a separate component may be required to apply a force to the first mask sheet MS1 toward the display substrate DS. According to an embodiment, the first mask sheet MS1 may be integrated with the second mask sheet MS2, which has a sufficient thickness and is arranged in the form of a grid to surround (or to extend around a periphery of) the first opening OP1, through the second layer L200, and may be in close contact with the display substrate DS because the magnetic force of the magnetic force portion 60 is sufficiently applied, and a separate component is not additionally required. Accordingly, a shadow phenomenon may be reduced or minimized, and thus, deposition quality of the display substrate DS may be improved.

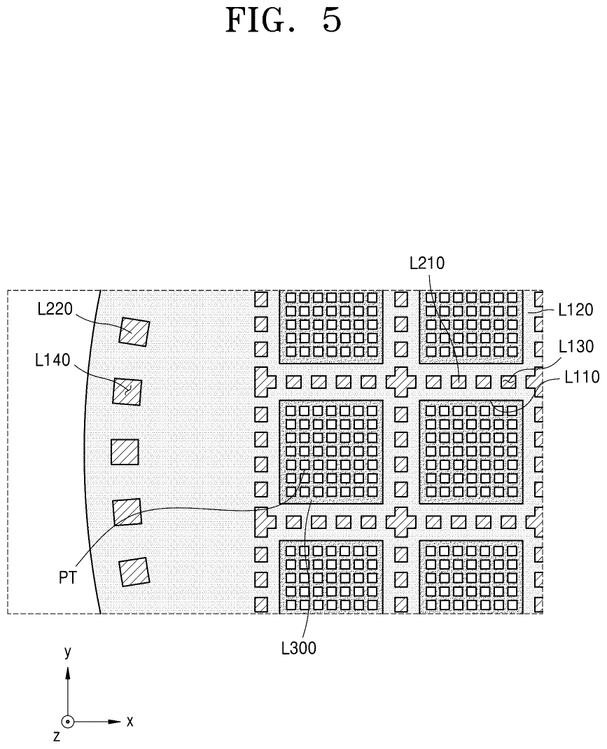

FIG. 5 is a schematic plan view of a mask assembly according to another embodiment. The mask assembly shown in FIG. 5 is similar to the above-described mask assembly shown in FIG. 4, and thus, hereinafter, differences are primarily described.

Referring to FIG. 5, in an embodiment, the first through portion L130 may be formed in the form of a plurality of dots that are arranged at the center in the width direction of the first rib L110 and are spaced apart from each other in the longitudinal direction of the first rib L110. In addition, the first through portion L130 may be formed in the form of a plurality of dots that are arranged at the center in the width direction of the second rib L120 and are spaced apart from each other in the longitudinal direction of the second rib L120. The first portion L210 of the second layer L200, which overlaps the first through portion L130, may be formed in the form of a line, as shown in FIG. 3, or may be formed in the form of a dot to correspond to the first through portion L130 formed in the form of a dot in FIG. 5.

In addition, in an embodiment, the second through portion L140 may be formed in the form of a plurality of dots spaced apart from each other along the circumference of the first layer L100. The second portion L220 of the second layer L200, which overlaps the second through portion L140, may be formed in the form of a line, as shown in FIG. 3, or may be formed in the form of a dot to correspond to the second through portion L140 formed in the form of a dot in FIG. 5.

In some embodiments, each of the first weld portion WP1 and the second weld portion WP2, which are disposed on the second layer L200 exposed by the first through portion L130 and the second through portion L140, may also be formed in the form of a plurality of dots.

As such, because the first through portion L130 and/or the second through portion L140 are formed in the form of a dot rather than in the form of a line, durability of the first mask sheet MS1 may be increased. For example, the first through portion L130 and the second through portion L140 are where the first mask sheet MS1, in particular, the second layer L200, is welded to the second mask sheet MS2, but accordingly, the first layer L100 has to be etched and, thus, is removed. When the first through portion L130 and/or the second through portion L140 are formed in the form of a dot, a portion of the first layer L100, which is etched and removed, may be reduced and durability of the first mask sheet MS1 may be increased.

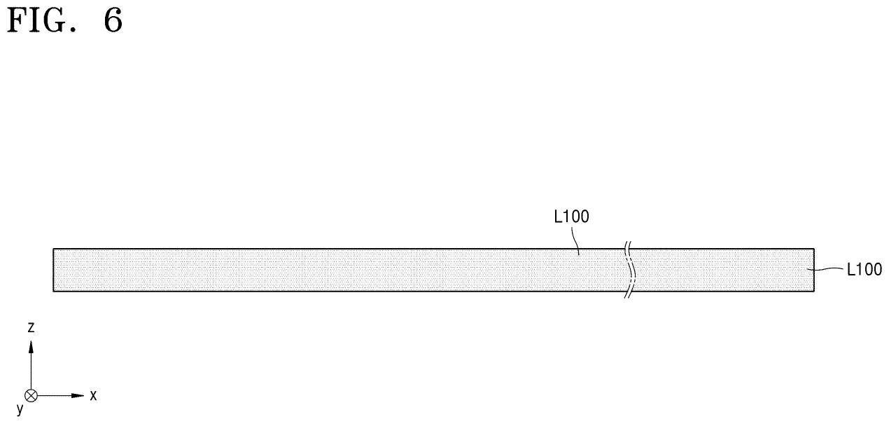

FIGS. 6 to 10 are schematic views of steps of a method of manufacturing a mask assembly according to an embodiment.

The method of manufacturing a mask assembly according to the present embodiment may be used to manufacture the above-described mask assembly, but the present disclosure is not limited thereto.

Referring to FIG. 6, the first mask sheet MS1 may be formed. For example, the first layer L100 may be arranged. The first layer L100 may include a silicon material, for example, at least one of silicon oxide (SiOₓ), silicon nitride (SiNₓ), and silicon oxynitride (SiOₓN_{y}), as described above. The first layer L100 may include a plurality of cell regions. Each cell region may refer to a region that is later etched to form the first opening OP1.

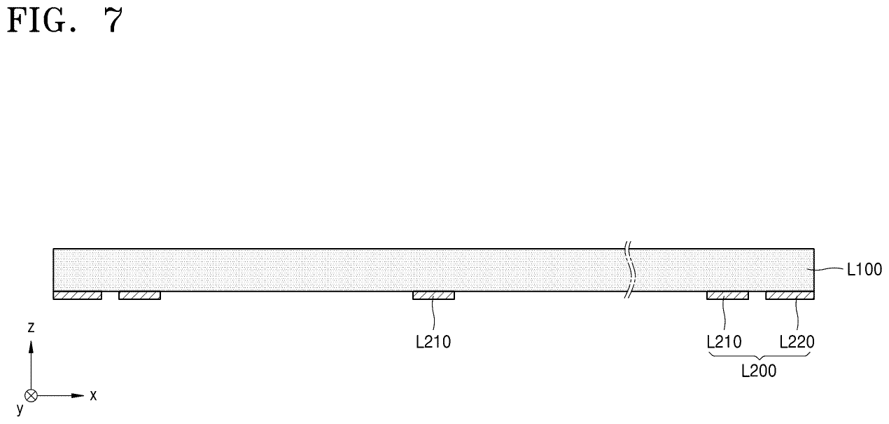

Referring to FIG. 7, the second layer L200 may be disposed on the first surface of the first layer L100. The second layer L200 may include a metal material, for example, at least one of aluminum (Al), copper (Cu), titanium (Ti), and molybdenum (Mo). The second layer L200 includes the first portion L210 and the second portion L220 and may be formed on the first layer L100. The first portion L210 may be arranged to surround (or to extend around a periphery of) the first opening OP1, that is, the cell region, which is formed later. The second portion L220 may be arranged along the circumference of the first layer L100. As described above, in an embodiment, the first portion L210 of the second layer L200 may be arranged in the form of a grid. In addition, the second portion L220 of the second layer L200 may be arranged in the form of a circular ring along the circumference of the first layer L100.

The first portion L210 and the second portion L220 may be formed by etching the second layer L200, or the first portion L210 and the second portion L220 may be formed by depositing a deposition material to be patterned.

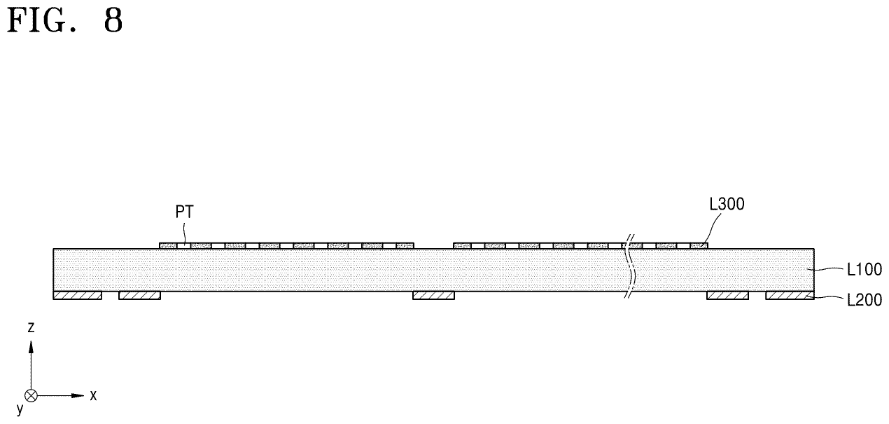

Referring to FIG. 8, the third layer L300 may be disposed on the second surface of the first layer L100. In an embodiment, the third layer L300 may include a metal material. In another embodiment, the third layer L300 may include an inorganic material. The third layer L300 may be arranged to include the plurality of pattern holes PT. In an embodiment, after the third layer L300 is arranged, a photoresist layer may be disposed on the third layer L300, and the plurality of pattern holes PT may be formed by etching the third layer L300. In another embodiment, a photoresist layer is patterned on the second surface of the first layer L100, and then the third layer L300 may be formed, by electroforming, to have the pattern holes PT between the patterned photoresist layers.

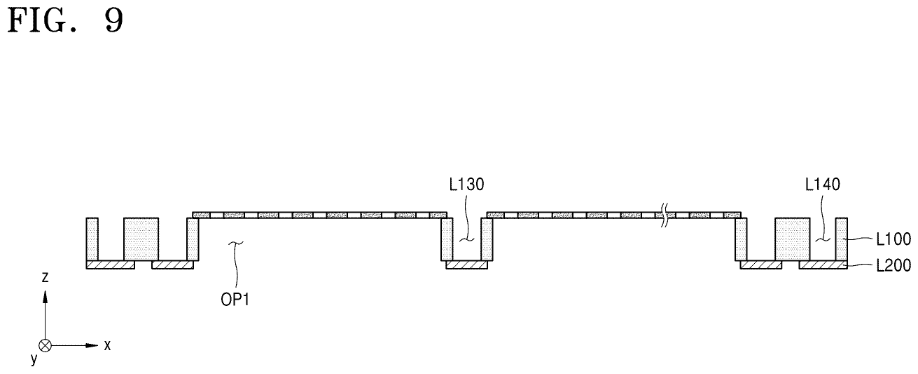

Referring to FIG. 9, the first layer L100 may be etched to form the first opening OP1, the first through portion L130, and the second through portion L140. As described above, the first opening OP1 may correspond to a cell. The first through portion L130 and the second through portion L140 expose the second layer L200 such that weld portions may be disposed thereon.

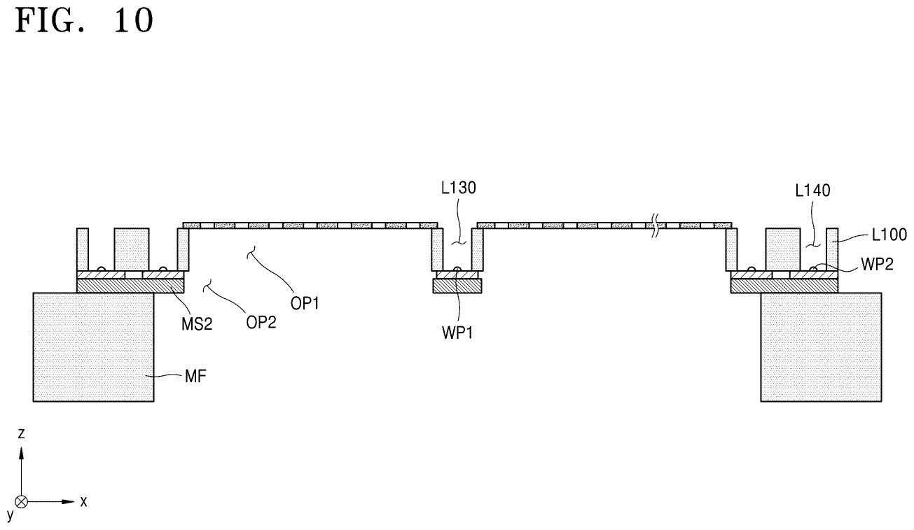

Referring to FIG. 10, the second layer L200 exposed by the first through portion L130, for example, the first portion L210 and the second layer L200 exposed by the second through portion L140, for example, the second portion L220, may be weld connected to the second mask sheet MS2 by the first weld portion WP1 and the second weld portion WP2, respectively. The second mask sheet MS2 may include a metal material and may have the second opening OP2 corresponding to the first opening OP1. In addition, because the second mask sheet MS2 is fixedly connected to the mask frame MF, an integrated mask assembly MA may be manufactured.

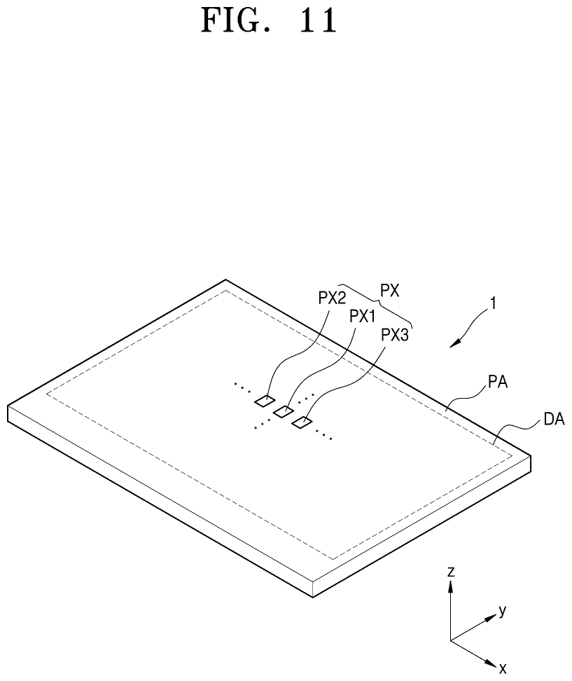

FIG. 11 is a schematic perspective view of a display apparatus manufactured by using an apparatus for manufacturing a display apparatus according to an embodiment.

Referring to FIG. 11, a display apparatus 1 may have a display region DA to display an image and a peripheral region PA at where an image is not displayed. The display apparatus 1 may provide an image through an array of a plurality of pixels two-dimensionally arranged on an x-y plane in the display region DA. Each pixel may include different sub-pixels. The sub-pixels may emit different colors; for example, the sub-pixels may each be one of a green sub-pixel, a red sub-pixel, and a blue sub-pixel.

In an embodiment, a plurality of sub-pixels may include a first sub-pixel PX1, a second sub-pixel PX2, and a third sub-pixel PX3. Hereinafter, for convenience of explanation, an embodiment in which the first sub-pixel PX1 is a green sub-pixel, the second sub-pixel PX2 is a red sub-pixel, and the third sub-pixel PX3 is a blue sub-pixel is described.

The first sub-pixel PX1, the second sub-pixel PX2, and the third sub-pixel PX3 may be regions that may emit green light, red light, and blue light, respectively, and the display apparatus 1 may provide an image by using light emitted from the sub-pixels.

The peripheral region PA is a region that does not provide an image and may entirely surround (e.g., may extend entirely around a periphery of) the display region DA. A driver or main voltage line for providing an electrical signal or power to pixel circuits may be arranged in the peripheral region PA. The peripheral region PA may include a pad, that is, an area to which an electronic element or a printed circuit board may be electrically connected.

As shown in FIG. 11, the display region DA may have a polygonal shape, such as a quadrangle. For example, the display region DA may have a rectangular shape in which a horizontal length is greater than a vertical length, a rectangular shape in which a horizontal length is less than a vertical length, or may have a square shape. In another embodiment, the display region DA may be a circle, an oval, or a polygonal shape, such as a triangle or a pentagon. In addition, the display apparatus 1 shown in FIG. 11 is a flat panel display apparatus, but the display apparatus 1 may be implemented in various forms, such as a flexible display apparatus, a foldable display apparatus, and a rollable display apparatus.

The display apparatus 1 may be used as a display screen of various products, for example, not only portable electronic devices, such as mobile phones, smartphones, tablet personal computers (PCs), mobile communication terminals, electronic organizers, electronic books, portable multimedia players (PMPs), navigation devices, ultra mobile PCs (UMPCs), etc., but also televisions, laptops, monitors, billboards, Internet of Things (IoT) devices, etc. Furthermore, the display apparatus 1 according to an embodiment may be used in wearable devices, such as smart watches, watch phones, glasses-type displays, head mounted displays (HMDs), and the like. Furthermore, the display apparatus 1 according to an embodiment may be used as a display for an instrument panel for vehicles, a center information display (CID) arranged on the center fascia or dashboard of vehicles, a room mirror display in lieu of a side-view mirror of vehicles, or a display arranged at the rear side of a front seat as an entertainment device for rear seat passengers of vehicles.

In addition, hereinafter, it is described that the display apparatus 1 includes an organic light-emitting diode (OLED) as a display element, but the display apparatus 1 of the present disclosure is not limited thereto. In another embodiment, the display apparatus 1 may be a light-emitting display apparatus including an inorganic light-emitting diode, that is, an inorganic light-emitting display apparatus. In another embodiment, the display apparatus 1 may be a quantum-dot light-emitting display apparatus.

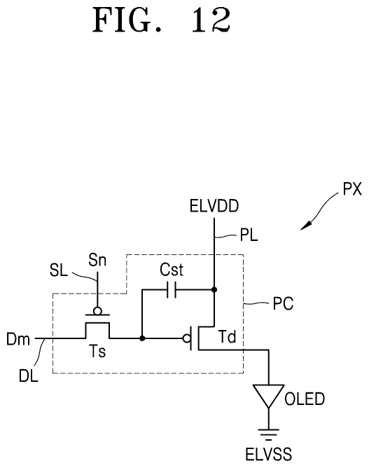

FIG. 12 is an equivalent circuit diagram of one pixel circuit PC included in a display apparatus manufactured by using an apparatus for manufacturing a display apparatus according to an embodiment. The pixel circuit PC may be electrically connected to a display element, and one display element may correspond to one pixel PX. For example, the display element may be an organic light-emitting diode OLED.

The pixel circuit PC may include a first transistor Td, a second transistor Ts, and a storage capacitor Cst. The second transistor Ts is a switching transistor and may be connected to a scan line SL and a data line DL and may be turned on by a switching signal input from the scan line SL to transmit a data signal input from the data line DL to the first transistor Td. The storage capacitor Cst may have one end electrically connected to the second transistor Ts and the other end electrically connected to a driving voltage line PL and may store a voltage corresponding to the difference between a voltage received from the second transistor Ts and a driving power voltage ELVDD supplied to the driving voltage line PL.

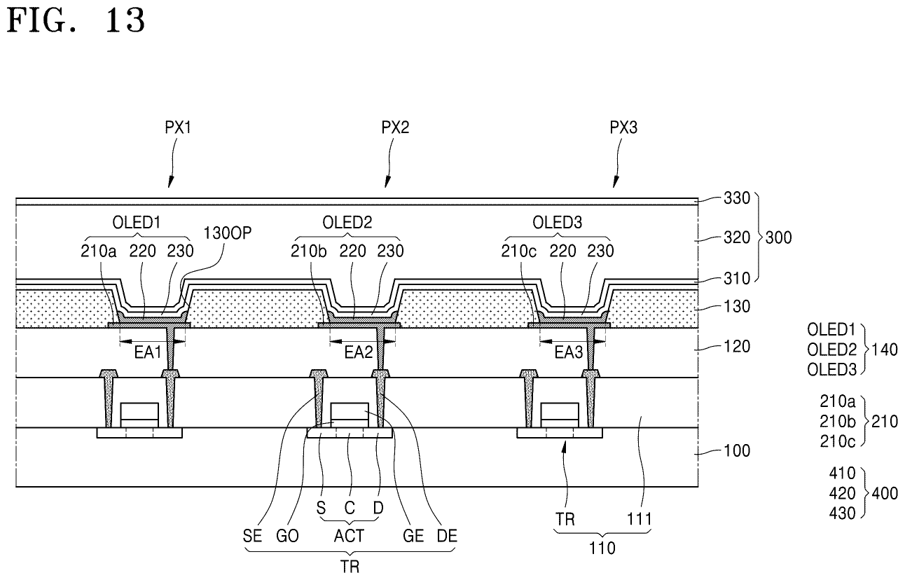

The first transistor Td is a driving transistor and may be connected to the driving voltage line PL and the storage capacitor Cst and may be configured to control the magnitude of a driving current flowing from the driving voltage line PL to the organic light-emitting diode OLED according to a voltage value stored in the storage capacitor Cst. The organic light-emitting diode OLED may emit light having a certain luminance according to the driving current. An opposite electrode 230 (see, e.g., FIG. 13) of the organic light-emitting diode OLED may receive an electrode power voltage ELVSS.

FIG. 12 illustrates an embodiment in which the pixel circuit PC includes two transistors and one storage capacitor, but the present disclosure is not limited thereto. For example, the number of transistors or the number of storage capacitors may vary according to the design of the pixel circuit PC.

FIG. 13 is a schematic cross-sectional view of the display apparatus shown in FIG. 11 manufactured by using an apparatus for manufacturing a display apparatus according to an embodiment.

Referring to FIG. 13, the display apparatus 1 may include the substrate 100, a pixel circuit layer 110 including a transistor TR, a via insulating layer 120 on the pixel circuit layer 110, a display element layer 140 disposed on the via insulating layer 120, and an encapsulation layer 300 on the display element layer 140.

The substrate 100 may have an upper surface on a plane extending in an x direction and a y direction. The substrate 100 may include a semiconductor material, for example, a Group IV semiconductor, a Group III-V compound semiconductor, or a Group II-VI compound semiconductor. For example, the substrate 100 may be a semiconductor substrate including a semiconductor material. In one embodiment, the substrate 100 may include silicon (Si). For example, the substrate 100 may include a silicon substrate (e.g., a silicon semiconductor substrate). For example, the substrate 100 may be a silicon wafer. The silicon wafer may be a monocrystalline silicon wafer, a polycrystalline silicon wafer, or an amorphous silicon wafer.

An organic light-emitting diode display apparatus using a semiconductor substrate as the substrate 100 may be referred to as an OLED on silicon (OLEDoS). Because the OLEDoS uses a semiconductor substrate as the substrate 100, a transistor manufacturing process commonly used in the semiconductor technology field may be applied to a display apparatus manufacturing process. Therefore, because ultra-small pixels may be formed and the ultra-small pixels may be controlled, the OLEDoS may display ultra-high resolution images.

In some embodiments, the type of substrate 100 is not limited to a semiconductor substrate. For example, the substrate 100 may include glass, a metal, or polymer resin. In addition, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multilayer structure including two layers, each including a polymer resin and a barrier layer arranged between the two layers and including an inorganic material (e.g., silicon oxide (SiO_{X}), silicon nitride (SiN_{X}), and/or silicon oxynitride (SiO_{X}N_{Y})), and various modifications may be made. Hereinafter, an embodiment in which the substrate 100 is a silicon substrate is primarily described.

The pixel circuit layer 110 may be disposed on the substrate 100. The pixel circuit layer 110 may include a plurality of pixel circuits respectively corresponding to the pixels, that is, the first sub-pixel PX1, the second sub-pixel PX2, and the third sub-pixel PX3, described above with reference to FIG. 11. Each of the plurality of pixel circuits may include a transistor and/or a storage capacitor as described above with reference to FIG. 12. The pixel circuit layer 110 may include at least one transistor TR and at least one insulating layer.

FIG. 13 illustrates an embodiment in which an organic light-emitting diode OLED, as a display element, is disposed above the substrate 100. When the organic light-emitting diode OLED is electrically connected to the pixel circuit PC, it may indicate that a pixel electrode 210 included in the organic light-emitting diode OLED is electrically connected to the transistor TR included in the pixel circuit PC (see, e.g., FIG. 12). For convenience of illustration, FIG. 13 illustrates an embodiment in which the transistor TR is connected to each of a first organic light-emitting diode OLED1, a second organic light-emitting diode OLED2, and a third organic light-emitting diode OLED3, and the transistor TR may correspond to the first transistor Td (see, e.g., FIG. 12).

The transistor TR may include a gate dielectric layer GO, a gate electrode GE, and an active region ACT. The transistor TR may be, for example, a metal-oxide-semiconductor field effect transistor (MOSFET) but is not limited thereto. In an embodiment, each of the transistors TR may be isolated from another by an element isolation region arranged between the transistors TR.

The active region ACT may be arranged in the substrate 100. The active region ACT may be formed as a portion of the substrate 100. The active region ACT may be arranged to extend in a first direction, for example, in the x direction, within the substrate 100. A portion of the substrate 100 may be recessed, and the active region ACT may be disposed on the recessed portion of the substrate 100. The active region ACT may include a channel region C, and a drain region D and a source region S respectively arranged at both sides (e.g., opposite sides) of the channel region C. Each of the drain region D and the source region S may be a region doped with impurities on the substrate 100 including a semiconductor material. The channel region C may overlap the gate electrode GE.

The gate dielectric layer GO may be arranged between the gate electrode GE and the active region ACT. The gate dielectric layer GO may include, for example, an inorganic insulating material, such as silicon oxide (e.g., SiO₂), silicon nitride (SiNₓ), silicon oxynitride (SiON), aluminum oxide (e.g., Al₂O₃), titanium oxide (e.g., TiO₂), tantalum oxide (e.g., Ta₂O₅), hafnium oxide (e.g., HfO₂), or zinc oxide (e.g., ZnO₂).

The gate electrode GE may be disposed on the active region ACT. The gate electrode GE may be arranged to intersect the active region ACT and extend in one direction, for example, in the y direction. The channel region C of the transistor TR may be formed in the active region ACT intersecting the gate electrode GE. For example, the gate electrode GE may overlap the channel region C of the transistor TR. The gate electrode GE may be disposed on the gate dielectric layer GO. The gate electrode GE may include a conductive material. For example, the gate electrode GE may include a metal nitride, such as titanium nitride (TiN), tantalum nitride (TaN), or tungsten nitride (WN), and/or a metal material, such as aluminum (Al), tungsten (W), copper (Cu), or molybdenum (Mo), or a semiconductor material such as doped polysilicon. The gate electrode GE may be formed as a multilayer structure or a single layer, each including the above-described material.

An interlayer insulating layer 111 may be disposed on the substrate 100 and may cover the transistor TR. The interlayer insulating layer 111 may include at least one of oxide, nitride, and oxynitride. The interlayer insulating layer 111 may have a single layer or a multilayer structure.

A drain electrode DE and a source electrode SE may be disposed on the interlayer insulating layer 111. The drain electrode DE and the source electrode SE may be respectively connected to the drain region D and the source region S of the active region ACT through contact holes (e.g., contact openings) provided in the interlayer insulating layer 111. Each of the drain electrode DE and the source electrode SE may include a material exhibiting excellent conductivity. Each of the drain electrode DE and the source electrode SE may include a conductive material including molybdenum (Mo), aluminum (Al), copper (Cu), or titanium (Ti) and may be formed as a multilayer or a single layer, each including the above-described material.

The via insulating layer 120 may be disposed on the pixel circuit layer 110. The via insulating layer 120 may be an organic insulating layer that covers upper surfaces of the drain electrode DE and the source electrode SE and has a generally flat upper surface, thereby acting as a planarization film. The via insulating layer 120 may include an organic material, such as acryl, benzocyclobutene (BCB), or hexamethyldisiloxane (HMDSO). The via insulating layer 120 is shown as a single layer but is not limited thereto and may be formed as a multilayer.

The display element layer 140 may be disposed on the via insulating layer 120. The display element layer 140 may include the first organic light-emitting diode OLED1, the second organic light-emitting diode OLED2, and the third organic light-emitting diode OLED3.

Each of the first to third organic light-emitting diodes OLED1, OLED2, and OLED3 may include a structure of a stack of the pixel electrode 210, an emission layer 220, and the opposite electrode 230. The first to third organic light-emitting diodes OLED1, OLED2, and OLED3 may each emit light having the same peak spectrum. For example, each of the first to third organic light-emitting diodes OLED1, OLED2, and OLED3 may emit white light. For example, the peak spectrum of each of the first to third organic light-emitting diodes OLED1, OLED2, and OLED3 may have peaks in a first wavelength region in a range of about 435 nm to about 490 nm, in a second wavelength region in a range of about 500 nm to about 590 nm, and in a third wavelength region in a range of about 600 nm to about 710 nm. The first to third organic light-emitting diodes OLED1, OLED2, and OLED3 emit light, and regions from which the light is emitted may be defined as a first emission region EA1, a second emission region EA2, and a third emission region EA3, respectively.

A plurality of pixel electrodes 210 may be disposed on the via insulating layer 120. Each of the pixel electrodes 210 may be electrically connected to the transistor TR through a contact hole (e.g., a contact opening) provided in the via insulating layer 120. Each of the pixel electrodes 210 may include a light-transmissive conductive layer formed of a light-transmissive conductive oxide, such as ITO, In₂O₃, or IZO, and a reflective layer formed of a metal, such as Al or Ag. For example, each of the pixel electrodes 210 may have a three-layer structure of ITO/Ag/ITO.

As shown in FIG. 13, the pixel electrodes 210 may include a first pixel electrode 210a, a second pixel electrode 210b, and a third pixel electrode 210c. When viewed in a direction perpendicular to the substrate 100, the first to third pixel electrodes 210a, 210b, and 210c may be arranged apart from each other.

A pixel-defining layer 130 may be disposed on the via insulating layer 120. The pixel-defining layer 130 may have an opening 130OP corresponding to each of the first to third sub-pixels PX1, PX2, and PX3. The opening 130OP in the pixel-defining layer 130 may expose at least a portion, for example, a central portion, of each of the pixel electrodes 210. In an embodiment, the first to third emission regions EA1, EA2, and EA3 may be defined as regions exposed by the opening 130OP in the pixel-defining layer 130. The pixel-defining layer 130 may include an organic insulating material and/or an inorganic insulating material. The pixel-defining layer 130 may include, for example, an organic material, such as polyimide or hexamethyldisiloxane (HMDSO).

A spacer for preventing mask scratches may be further provided on the pixel-defining layer 130. In an embodiment, the spacer may be integrally formed with the pixel-defining layer 130. For example, the spacer and the pixel-defining layer 130 may be concurrently (or simultaneously) formed in the same process by using a halftone mask process.

The emission layer 220 may be disposed on the pixel electrodes 210. The emission layer 220 may be arranged to cover the pixel electrodes 210 exposed by the opening 130OP in the pixel-defining layer 130. In an embodiment, the emission layer 220 may be integrally formed over the plurality of pixel electrodes 210.

The emission layer 220 may emit light of a certain color. For example, the emission layer 220 may emit white light.

In an embodiment, the emission layer 220 may include a polymer or oligomer organic material. The emission layer 220 may include an organic emission layer. For example, the emission layer 220 may include a polymer material, such as a polyphenylene vinylene (PPV)-based polymer material and a polyfluorene-based polymer material. The emission layer 220 may be formed by screen printing, inkjet printing, laser induced thermal imaging (LITI), etc. However, the present disclosure is not limited thereto, and the emission layer 220 may include an inorganic light-emitting material or may include quantum dots.

In an embodiment, a functional layer may be disposed under or above the emission layer 220. The functional layer may include a hole injection layer (HIL), a hole transport layer (HTL), an electron transport layer (ETL), and/or an electron injection layer (EIL). The functional layer may be integrally formed over the plurality of pixel electrodes 210 and may be patterned to correspond to each of the plurality of pixel electrodes 210.

The opposite electrode 230 may be disposed on the pixel electrodes 210 and may overlap the pixel electrodes 210. The opposite electrode 230 may be disposed on the emission layer 220. The opposite electrode 230 may include a conductive material having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In some embodiments, the opposite electrode 230 may further include a layer including ITO, IZO, ZnO, or In₂O₃ on the (semi) transparent layer including the aforementioned material. The opposite electrode 230 may be integrally formed to entirely cover the substrate 100.

The encapsulation layer 300 may be disposed on the opposite electrode 230. The encapsulation layer 300 may be arranged to cover the first to third organic light-emitting diodes OLED1, OLED2, and OLED3. The encapsulation layer 300 may include at least one inorganic encapsulation layer and at least one organic encapsulation layer. In an embodiment, the encapsulation layer 300 may include a first inorganic encapsulation layer 310, an organic encapsulation layer 320 on the first inorganic encapsulation layer 310, and a second inorganic encapsulation layer 330.

The first inorganic encapsulation layer 310 and the second inorganic encapsulation layer 330 may each include one or more inorganic materials from among an aluminum oxide, a titanium oxide, a tantalum oxide, a hafnium oxide, a zinc oxide, a silicon oxide, a silicon nitride, and a silicon oxynitride. The organic encapsulation layer 320 may include a polymer-based material. The polymer-based material may include an acrylic resin, an epoxy-based resin, polyimide, and polyethylene. In an embodiment, the organic encapsulation layer 320 may include acrylate. The organic encapsulation layer 320 may be formed by curing a monomer or applying a polymer. The organic encapsulation layer 320 may have transparency.

A touch sensor layer may be disposed on the encapsulation layer 300, and an optical functional layer may be disposed on the touch sensor layer. The touch sensor layer may obtain coordinate information according to an external input, for example, a touch event. The optical functional layer may reduce reflectivity of light (e.g., external light) incident on a display apparatus from the outside and/or may improve the color purity of light emitted from the display apparatus. In an embodiment, the optical functional layer may include a retarder and/or a polarizer. The retarder may be of a film type or a liquid crystal coating type and may include a λ/2 retarder and/or a λ/4 retarder. The polarizer may also be of a film type or a liquid crystal coating type. The film type may include a stretchable synthetic resin film, and a liquid crystal coating type may include liquid crystals arranged in a certain array. The retarder and the polarizer may further include a protective film.

An adhesive member may be arranged between the touch sensor layer and the optical functional layer. The adhesive member may employ any general adhesive that is well-known in the field of technology without limitation. In an embodiment, the adhesive member may be a pressure sensitive adhesive (PSA).

According to embodiment, a mask assembly may be better aligned with a display substrate, and thus, deposition quality of a deposition material may be improved.

It should be understood that the embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A mask assembly comprising:
a mask frame having an opening region; and
a first mask sheet covering the mask frame and comprising:
a first layer comprising a plurality of first ribs extending in a first direction and a plurality of second ribs extending in a second direction crossing the first direction and having a plurality of first openings defined by the first ribs and the second ribs;
a second layer on a first surface of the first layer and extending around the first openings; and
a third layer on a second surface of the first layer and having a plurality of pattern holes overlapping the first openings.

2. The mask assembly of claim 1, wherein the first layer further comprises a first through portion extending from a center of a width of the first ribs in a longitudinal direction of the first ribs and extending from a center of a width of the second ribs in a longitudinal direction of the second ribs.

3. The mask assembly of claim 2, wherein, when viewed from the second surface of the first layer, the second layer covers the first through portion such that the second layer is exposed through the first through portion.

4. The mask assembly of claim 3, wherein the first mask sheet further comprises a first weld portion on the second layer exposed through the first through portion, and
wherein the first weld portion is arranged along the first through portion in a plan view.

5. The mask assembly of claim 4, wherein, in a plan view, the first through portion, the second layer, and the first weld portion overlap each other.

6. The mask assembly of claim 4, wherein the mask assembly further comprises a second mask sheet having second openings corresponding to the first openings, and
wherein the second mask sheet is welded to the second layer by the first weld portion.

7. The mask assembly of claim 2, wherein the first through portion is formed in the form of a line in an extension direction of the first ribs and an extension direction of the second ribs.

8. The mask assembly of claim 2, wherein the first through portion is formed in the form of a plurality of dots that are spaced apart from each other in the longitudinal direction of the first ribs and the longitudinal direction of the second ribs.

9. The mask assembly of claim 1, wherein the first layer further comprises a second through portion extending along a circumference of the first layer.

10. The mask assembly of claim 9, wherein, when viewed from the second surface of the first layer, the second layer covers the second through portion such that the second layer is exposed by the second through portion.

11. The mask assembly of claim 10, wherein the first mask sheet further comprises a second weld portion on the second layer exposed through the second through portion, and
wherein the second weld portion is arranged along the second through portion in a plan view.

12. The mask assembly of claim 9, wherein the second through portion is formed in the form of a line extending along the circumference of the first layer.

13. The mask assembly of claim 9, wherein the second through portion is formed in the form of a plurality of dots that are spaced apart from each other along the circumference of the first layer.

14. A method of manufacturing a mask assembly, the method comprising:
arranging a first layer comprising a cell region;
arranging, on a first surface of the first layer, a second layer comprising a metal material to extend around a periphery of the cell region;
forming a first opening by etching the cell region of the first layer;
forming a first through portion overlapping the second layer by etching the first layer to expose the second layer; and
welded the exposed second layer to a mask sheet through the first through portion.

15. The method of claim 14, wherein, in a plan view, the first through portion is formed in the form of a grid.

16. The method of claim 14, further comprising arranging, on the first surface of the first layer, the second layer along a circumference of the first layer.

17. The method of claim 16, further comprising forming a second through portion by etching the first layer to expose the second layer arranged along the circumference of the first layer.

18. The method of claim 17, wherein the second through portion is formed in the form of a line along the circumference of the first layer.

19. The method of claim 17, wherein the second through portion is formed in the form of a plurality of dots that are spaced apart from each other along the circumference of the first layer.

20. The method of claim 17, further comprising welding the exposed second layer to the mask sheet through the second through portion.
